(19) United States
(12) Patent Application Publication
(10) Pub. No.: US 2002/0076876 A1
(43) Pub. Date: Jun. 20, 2002

(54) Method for manufacturing semiconductor devices having ESD protection

(76) Inventors: Ming-Dou Ker, Hsin Chu (TW); Wen-Yu Lo, Taichung County (TW); Peir-Jy Hu, Hsin Chu (TW)

Correspondence Address: BIRCH STEWART KOLASCH & BIRCH, PO BOX 747, FALLS CHURCH, VA, 22040-0747, US

(21) Appl. No.: 09/736,204

(22) Filed: Dec. 15, 2000

(51) Int. Cl. H01L 21/338; H01L 21/8238; H01L 21/04

(52) U.S. Cl. 438/218; 438/184; 438/228; 438/207

(57) ABSTRACT

A Method for manufacturing semiconductor devices having ESD protection. The method includes the steps of providing a semiconductor substrate having a well region, forming a gate structure on the semiconductor substrate, the gate structure including an oxide layer, a gate electrode on said oxide layer, and two spacer sidewalls, forming a source region within the well region at one side of the gate structure, forming a drain region within the well region at the other side of the gate structure, forming lightly doped source/drain regions in the well region and beneath the spacer walls of the gate structure wherein the lightly doped source/drain regions have the same conductivity type as the drain region and, and performing an implant with the same conductivity type as the well region as to form an ESD implantation region. The ESD implantation region is located under the diffusion region that is between the drain contact and the poly gate of output NMOS, but without covering the region right under the drain contact. Therefore, the ESD current is discharged through the ESD-implanted region to the substrate without causing current crowding under the drain contact as to burn out the drain contact.

### BACKGROUND OF THE INVENTION

A. Field of the Invention

The present invention relates to a method for manufacturing semiconductor devices having electrostatic discharge (ESD) protection, and more particularly to an implantation method employing a uniform current distribution for ESD protection.

B. Description of the Related Art

ESD (electrostatic discharge) damage has become one of the main reliability concerns for the IC (integrated circuit) products. The scaled-down MOS devices and thinner gate oxide have become more vulnerable to ESD stress since the CMOS technology has developed into the sub-quarter-micron regime. For general industrial specification, the input and output of the IC products have to sustain the human-body-model ESD stress above 2000 V. Therefore, the ESD protection circuits have to be laid near the input and output pads of the IC to protect the IC from damage.

In the output buffers of CMOS IC's, the output NMOS and PMOS devices are often designed with large device dimension (W/L) to provide the required driving current to the external loads. The large-sized output NMOS and PMOS also work as the ESD-protection devices to protect themselves. For example, in the 0.35-μm CMOS process, an output NMOS with a device dimension of W/L=300/0.5 (μm/μm) can sustain an ESD level greater than 2000V by following some specific ESD design rules in the 0.35-μm CMOS process. One of the effective process methods to improve the ESD level of the output NMOS and PMOS is the ESD implantation.

The device structure of an output NMOS is shown in FIG. 1, and its corresponding layout top view is shown in FIG. 2. The output NMOS is often drawn with a wider spacing S_{DG} in the layout. The typical value for this spacing S_{DG} is around 3˜5 μm for the NMOS to sustain a high ESD level. In the sub quarter-micron CMOS technology, the NMOS (also PMOS) is formed with a LDD (lightly-doped drain) structure to overcome the hot carrier effect in the short-channel devices, as shown in FIG. 1. However, the LDD structure can generates an undesired peak structure in the drain region near the surface channel. Once a positive ESD voltage shocks such NMOS, the ESD current is focused and discharged through the LDD peak in the NMOS device structure. The ESD current is conducted into the drain region through the drain contact and then to the LDD peak, as shown in FIG. 3 illustrating the ESD current path in the NMOS with a LDD structure. Because the LDD peak is the nearest region close to the grounded source, the first breakdown due to the high-energy discharge across the drain of the NMOS occurs in this LDD peak region. Compared to the drain N+ diffusion junction depth (˜0.2 μm), the LDD peak region often has a much shallower junction depth (˜0.02 μm) which leads to a smaller junction area for ESD current discharge. Therefore, the NMOS device with LDD structure has a much lower ESD level.

To improve the ESD level of the output NMOS, a conventional method is used to add an extra ESD-implantation process step in the CMOS process to form a drain region without the LDD peak structure, as shown in FIG. 4 and FIG. 5 illustrating the layout of FIG.4. An output NMOS with no LDD peak structure in its drain region can naturally sustain a much higher ESD level. Such ESD implantation can be performed before or after the formation of the sidewall spacers on the gate oxide. This conventional method for an NMOS without LDD peak structure had been disclosed in some U.S. Pat. such as No. 5,416,036 by C. C. Hsue, No. 5,455,444 by C. C. Hsue, No. 5,496,751 by Y. H. Wei, No. 5,529,941 by T. Y. Huang, No. 5,585,299 by C. C. Hsue, No. 5,672,527 by J. S. Lee, and No. 5,733,794 by P. Gilbert, et al. As shown in FIG. 4, the LDD peak in the NMOS has been covered or removed by the ESD implantation with the extra N-type region to prevent from the ESD degradation due to the LDD peak in the NMOS structure. However, such method suffers from the undesired hot electron effect and the worst short channel effect while compared to the normal LDD MOSFET structure. Therefore, such NMOS device has a larger channel length to reduce the hot carrier effect of IC circuits.

Another conventional method for improving ESD level of the NMOS with LDD peak structure is to generate a low-breakdown-voltage junction in the drain region so that the ESD current is discharged through the low-breakdown-voltage junction rather than the LDD peak structure, as illustrated in FIG. 6 and FIG. 7. A highly doped P+ material is implanted around the junction under the drain contact to reduce the breakdown voltage at this junction region. As shown in FIG. 7, the ESD implantation region is only located at the center of the drain region including the junction under the drain contact. The junction breakdown voltage is dependent on the doping concentrations of the p and n diffusions around the p-n junction. For example, in a 0.25-μm 3.3V CMOS process, the original junction breakdown voltage of an output NMOS with LDD structure is about 8 V. If such an output NMOS is implanted with the P+ (boron) material, the junction breakdown voltage shall drop to only about 5V. Therefore, the junction region with such ESD implantation has a lower breakdown voltage by adding an extra mask layer and some additional process steps in the CMOS process flow to form the output NMOS with a lower junction breakdown voltage. This kind of process methods had been disclosed in some U.S. Pat. such as No. 5,374,565 by C. C. Hsue and J. Ko, No. 5,581,104 by T. A. Lowrey and R. W. Chance, No. 5,674,761 by K. Z. Chang, and No. 5,953,601 by R. Y. Shiue et al. The ESD current discharging path in such design is illustrated in FIG. 8. The junction region right under the drain contact has a lower breakdown voltage due to the ESD implantation such that the ESD current tends to be crowding at this narrow junction region. As the ESD current is conducted from the drain contact material to the p substrate, the ESD current discharging through the narrow junction region causes the higher heat which can melt the metal material in the drain contact, resulting in an undesired phenomenon known as “contact spiking”.

### SUMMARY OF THE INVENTION

The principal object of the invention is to provide a new ESD implantation method for application in the ESD protection devices with the uniform current distribution such that the ESD level of devices manufactured in the sub-quarter-micron CMOS processes is significantly improved. An ESD implantation method for manufacturing semiconductor devices having ESD (Electrostatic Discharge) protection includes the steps of providing a semiconductor substrate having a well region, forming a gate structure on the semiconductor substrate, the gate structure including an oxide layer, a gate electrode on said oxide layer, and two spacer sidewalls, forming a source region within the well region at one side of the gate structure, forming a drain region within the well region at the other side of the gate structure, forming lightly doped source/drain regions having the same conductivity type as the drain region and formed in the well region and beneath the spacer walls of the gate structure, and performing an implant with the same conductivity type as the well region as to form an ESD implantation region. The ESD implantation region is located under the diffusion region that is between the drain contact and the poly gate of output NMOS, but without covering the region right under the drain contact. Therefore, the ESD current is discharged through the ESD-implanted region to the substrate without causing current crowding under the drain contact as to bum out the drain contact.

### BRIEF DESCRIPTION OF THE DRAWINGS

These and other objects and advantages of the present invention will become apparent by referring to the following description and accompanying drawings wherein:

FIG. 1 is a cross-sectional view of a conventional NMOS device with LDD structure.

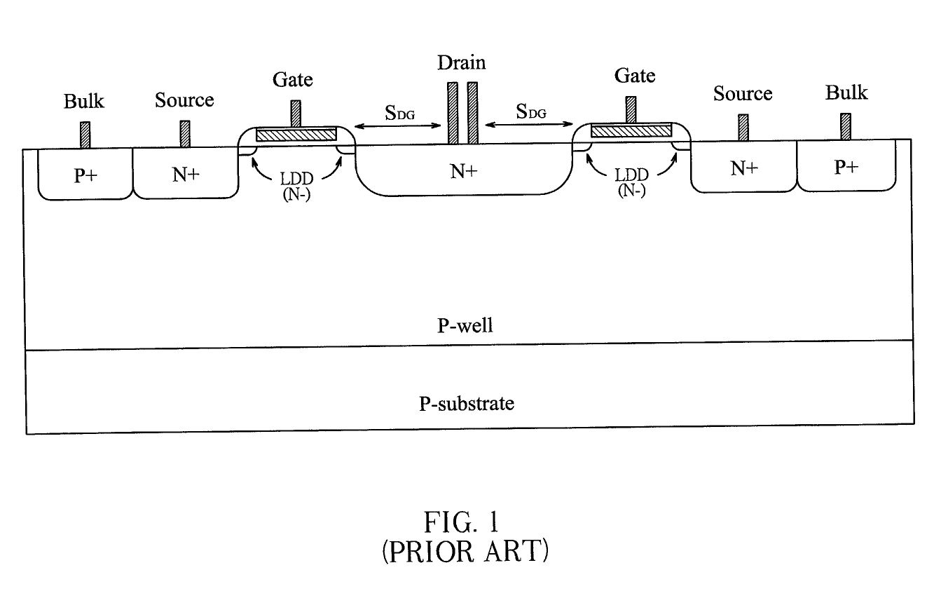

FIG. 2 is a top view of FIG. 1.

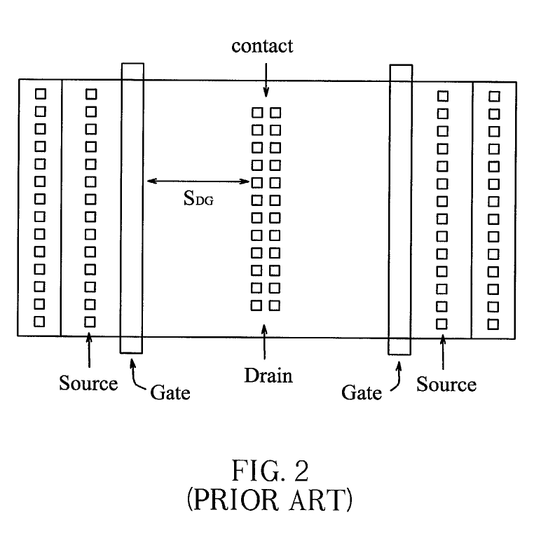

FIG. 3 is the cross-sectional view illustrating the ESD current path in the conventional NMOS with the LDD structure.

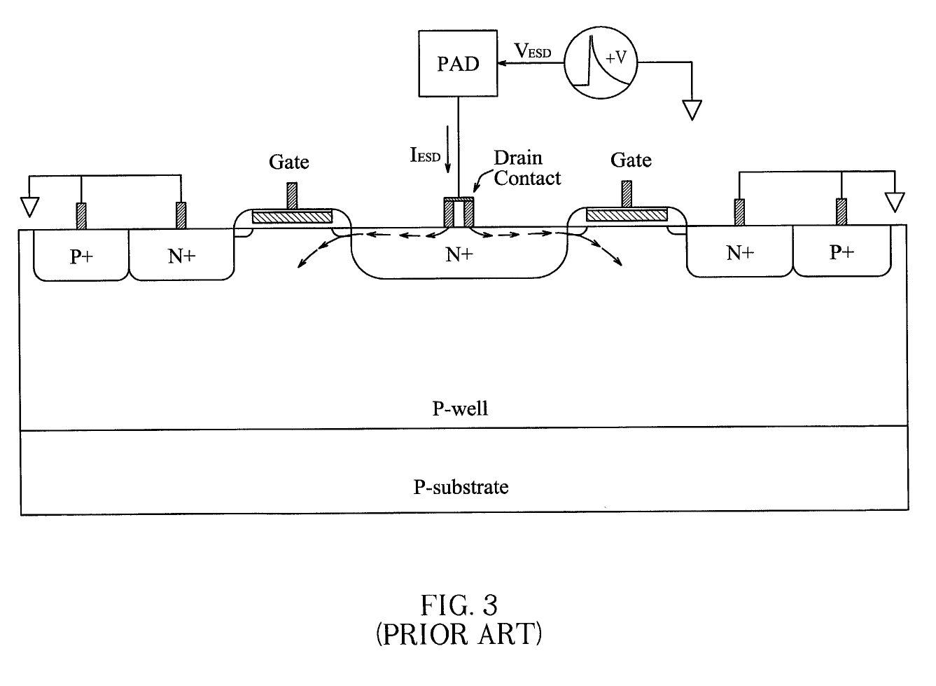

FIG. 4 is a cross-sectional view illustrating the conventional ESD implantation with N-type doping.

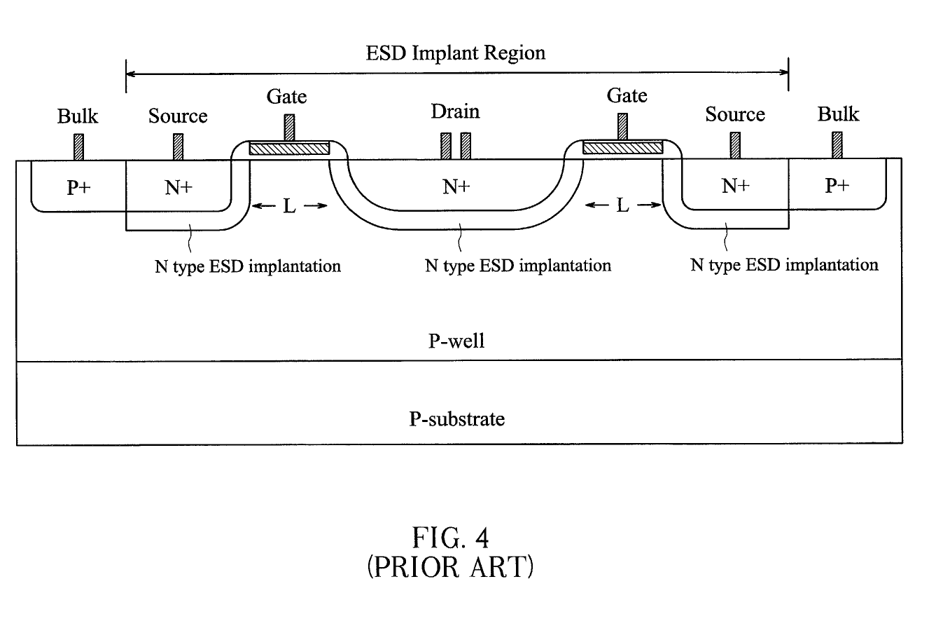

FIG. 5 is a top view of FIG. 4.

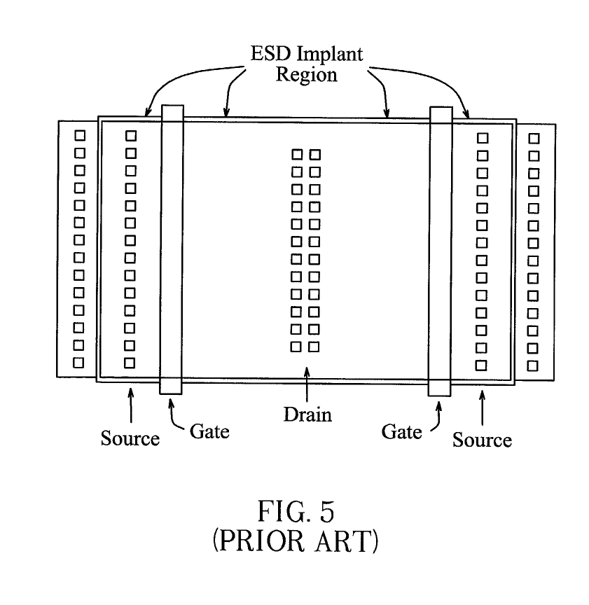

FIG. 6 is a cross-sectional view illustrating the conventional ESD implantation with P-type doping.

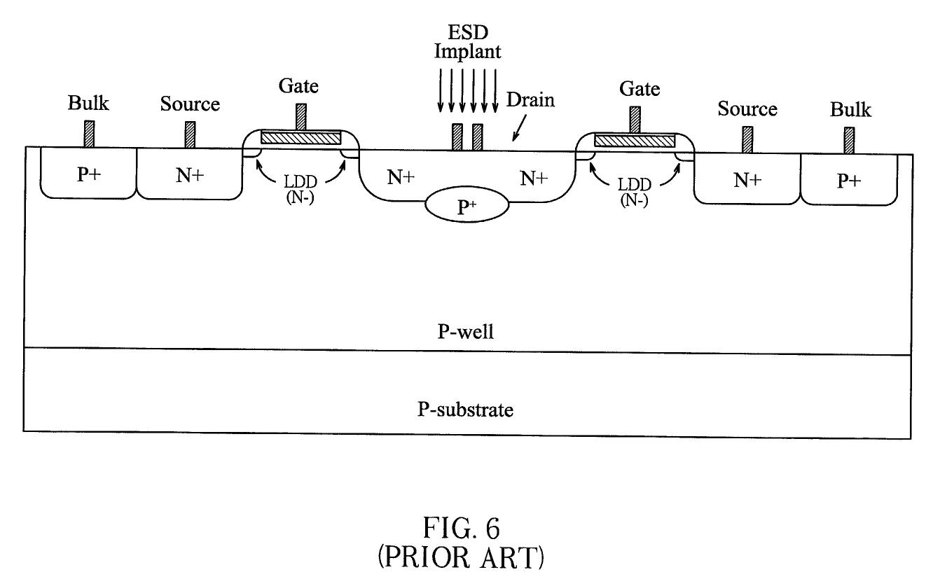

FIG. 7 is a top view of FIG. 6.

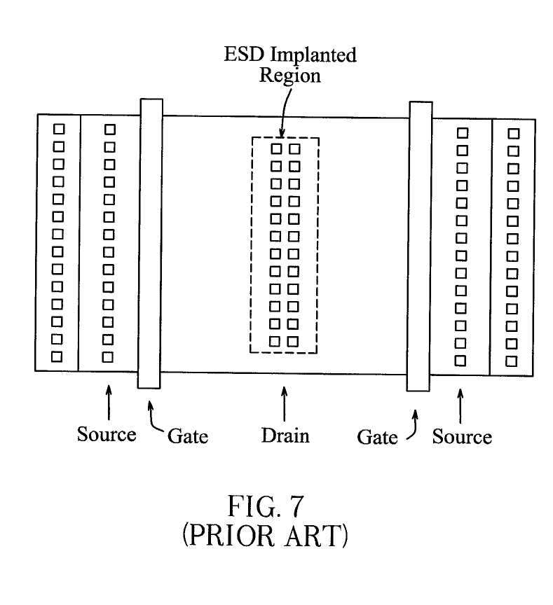

FIG. 8 is a cross-sectional view illustrating the ESD current path in the NMOS with P-type ESD implantation;

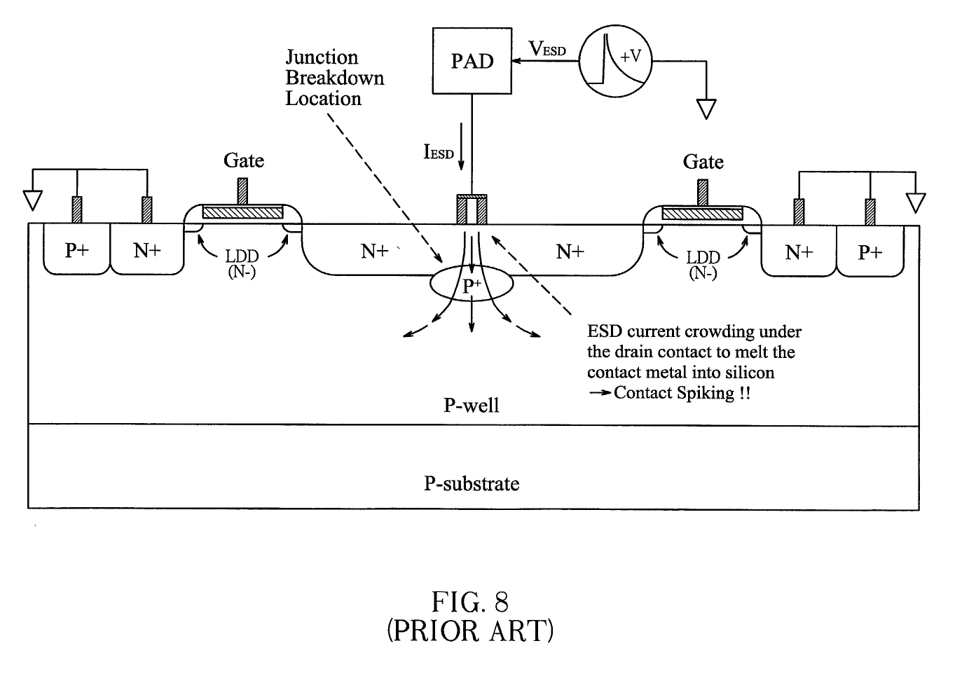

FIG. 9 is a cross-sectional view illustrating the P-type ESD implantation without current-crowding effect on the drain contact according to the first embodiment of the invention.

FIG. 10 is a top view of FIG. 9.

FIG. 11 is a cross-sectional view illustrating the ESD current discharging path according to the first embodiment of the invention.

FIG. 12 is a top view showing one of the layout patterns according to the first embodiment of the invention.

FIG. 13 is a top view showing one of the layout patterns according to the first embodiment of the invention.

FIG. 14 is a schematic view illustrating the application of the invention in a 1.8 V/3.3 V-tolerant I/O pad.

FIG. 15 is a top view showing one of the layout patterns for using in the stacked NMOS in the 1.8 V/3.3 V-tolerant I/O pad according to the first embodiment of the invention.

FIG. 16 is a cross-sectional view of the second embodiment of the invention with p-type ESD implantation.

FIG. 17 is a cross-sectional view of the second embodiment of the invention with p-type ESD implantation in the Field-Oxide Device for ESD Protection design.

FIG. 18 is a cross-sectional view of the second embodiment of the invention p-type ESD implantation.

### DETAIL DESCRIPTION OF THE INVENTION

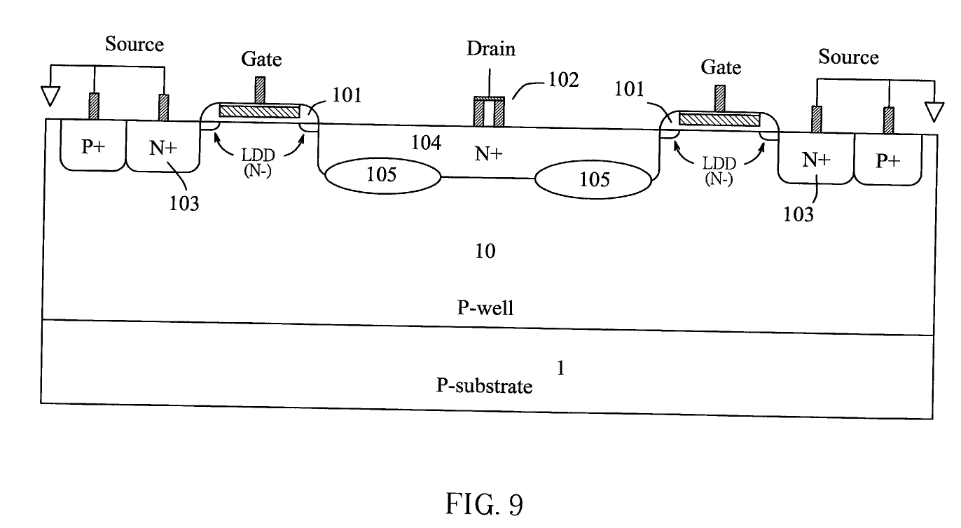

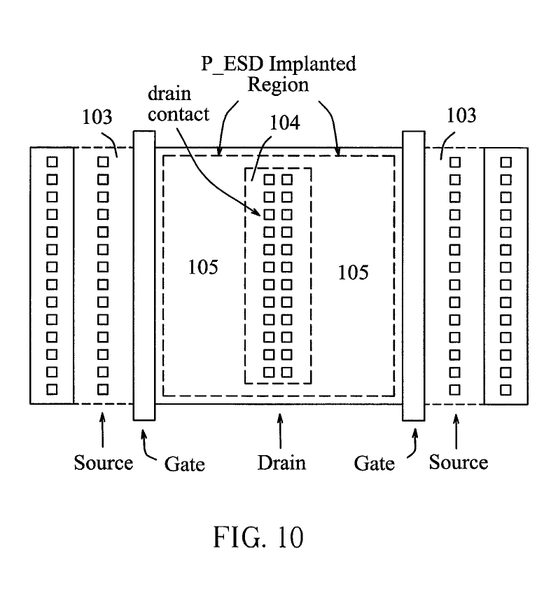

FIG. 9 illustrates the ESD implantation within an NMOS device and FIG. 10 is the corresponding layout of FIG. 9. According to the first embodiment of the invention, an NMOS with ESD protection includes a gate structure with spacer sidewalls 101, a source region 103 and a drain region 104 beneath a drain contact 102. The LDD (lightly doped drain) regions formed underneath the sidewalls 101 and extending from the source region 103 and drain region 104 respectively is to reduce the hot carrier effect. For example, a typical LDD region is formed by phosphorous implantation or arsenic ion implantation.

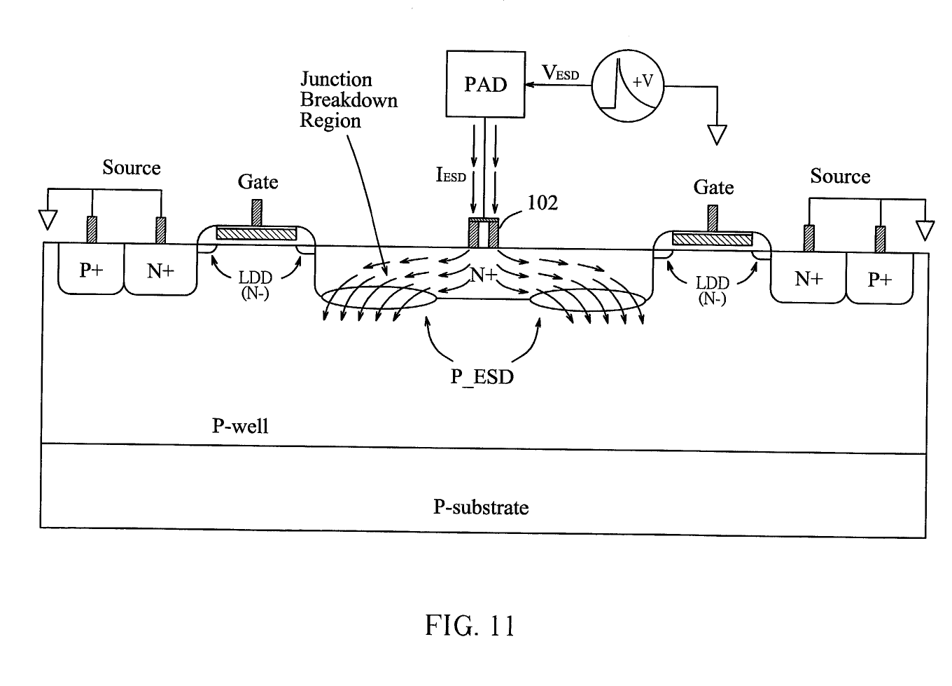

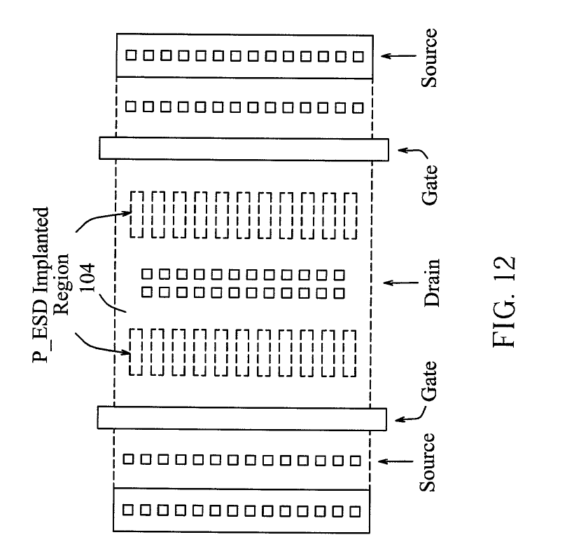

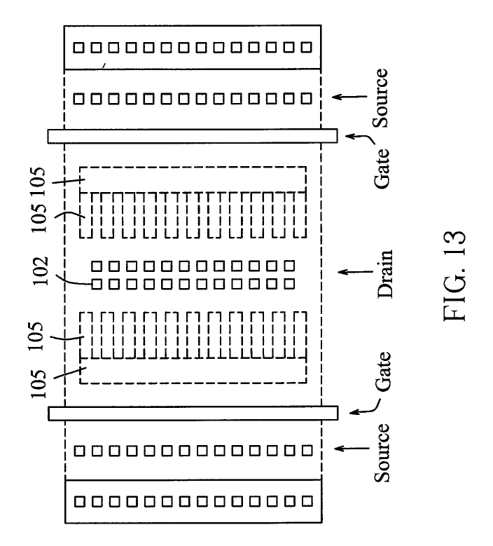

Referring to FIG. 9 and 10, an ESD implantation region 105 with a p-type doping concentration higher than that of the p-well is formed beneath the drain region 104. The layout pattern of the ESD implantation region 105 surrounding the drain contact 102 with respect to the top view as shown in FIG. 10 can be further drawn as a plurality of separated small blocks in parallel to the drain contact 102, as shown in FIG. 12. By these uniformly distributed small blocks of ESD implantation, the ESD current discharging through the drain region 104 has a more uniform current distribution to dissipate the ESD-generated heat, which results in an improved ESD level. FIG. 13 shows an alternative pattern of FIG. 12 by forming the ESD implantation region 105 with a plurality of separated small blocks and two long stripe which also have the effect of uniform current distribution. The junction embedded in the ESD implantation region 105 has a lower breakdown voltage because of its higher doping concentration across the p-n junction in the drain region. The ESD implantation region 105 still keeps the original junction breakdown voltage as to be broken first to discharge the ESD current. FIG. 11 illustrates the ESD current path for an ESD-implanted NMOS device. A positive high voltage is applied to the pad of an output NMOS with the VSS relatively grounded and is clamped by the junction region between drain contact 102 and the ESD implantation region 105 bypassing the current. The ESD current path depicted in FIG. 11 has more uniform current distribution from the drain contact 102 to the p-substrate. The ESD current flowing from the drain current 102 does not cause the current crowding at the junction region right under the drain contact 102, that is, the contact spiking phenomenon can hardly occur in the output NMOS device.

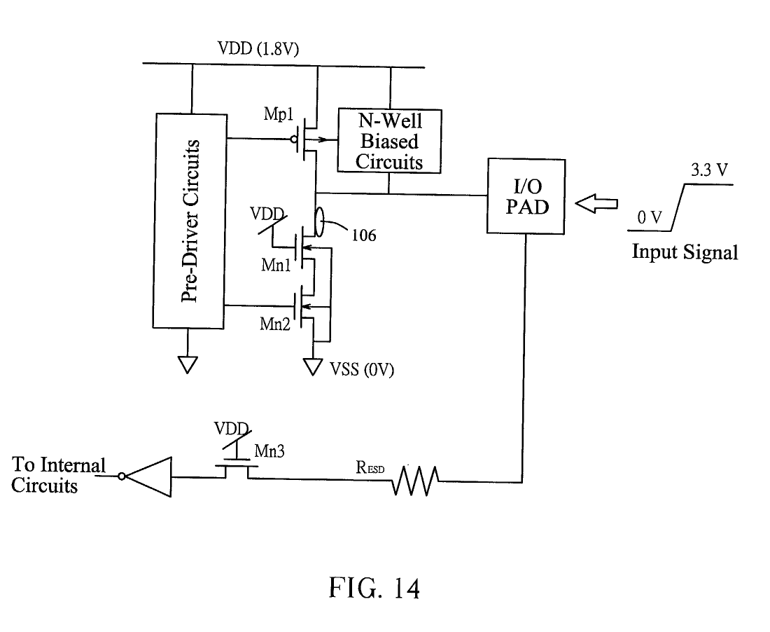

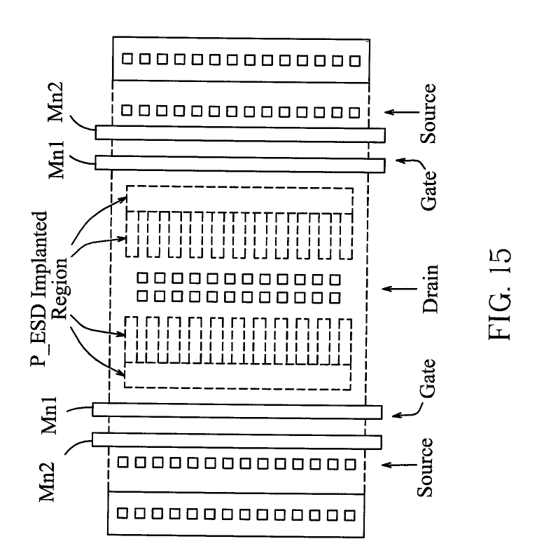

The ESD implantation region 105 can be also applied to the increase the ESD level of the 1.8 V/3.3 V-tolerant I/O circuits in the sub-quarter-micron CMOS IC, as shown in FIG. 14 and FIG. 15 for the layout of the stacked NMOS (Mn1 and Mn2). The poly-silicon gates of Mn1 and Mn2 are drawn close to each other, and the ESD implantation region 106 is disposed between the drain contact and the poly-silicon gate of Mn1.

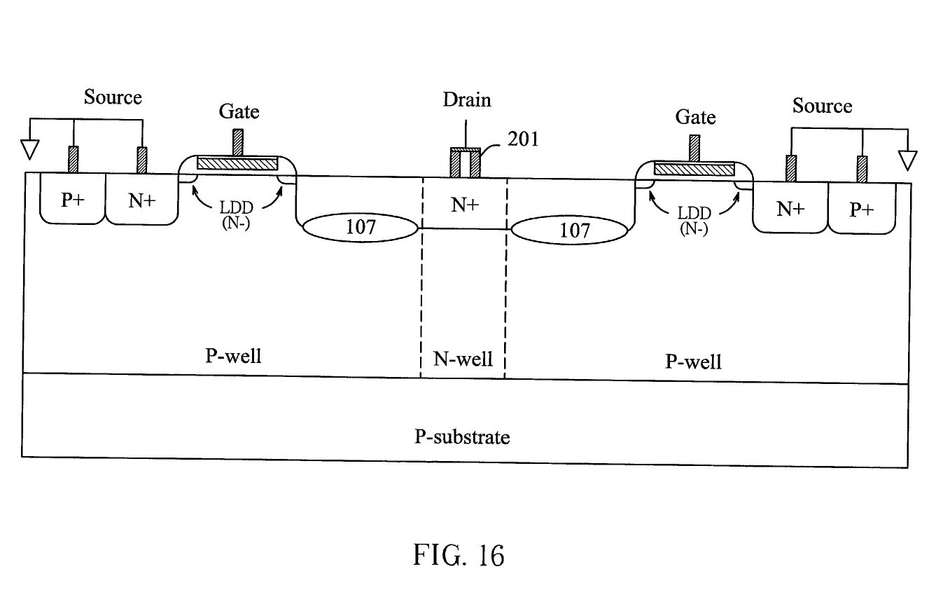

Referring to FIG. 16, except the ESD implantation region 107 similar to the ESD implantation region 105 of the first embodiment, the second embodiment of the invention further adds an additional N-well right under the drain contact 201, which significantly reduces the drain contact spiking effect because the N-well has a much deeper junction depth (˜2 μm) than that of the normal drain junction (˜0.15 μm) in sub-quarter-micron CMOS processes, thus sustaining a higher ESD stress.

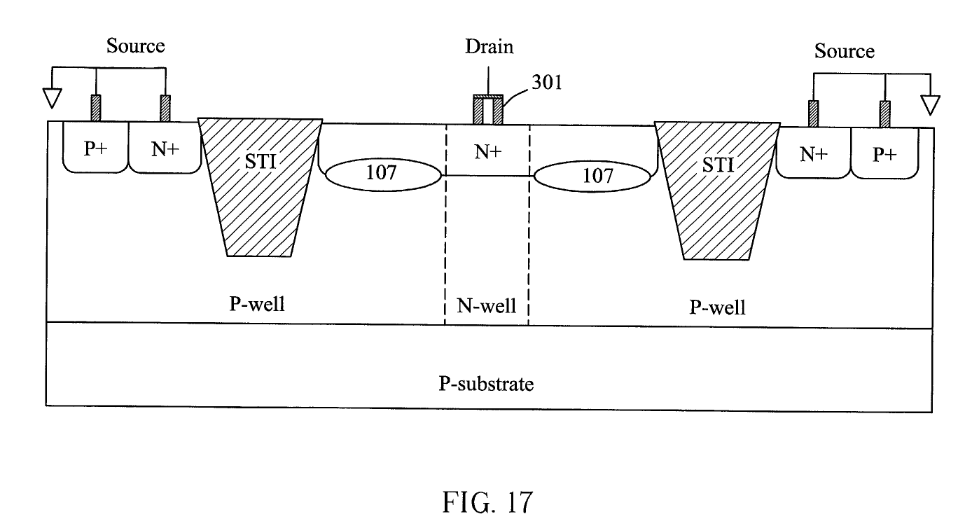

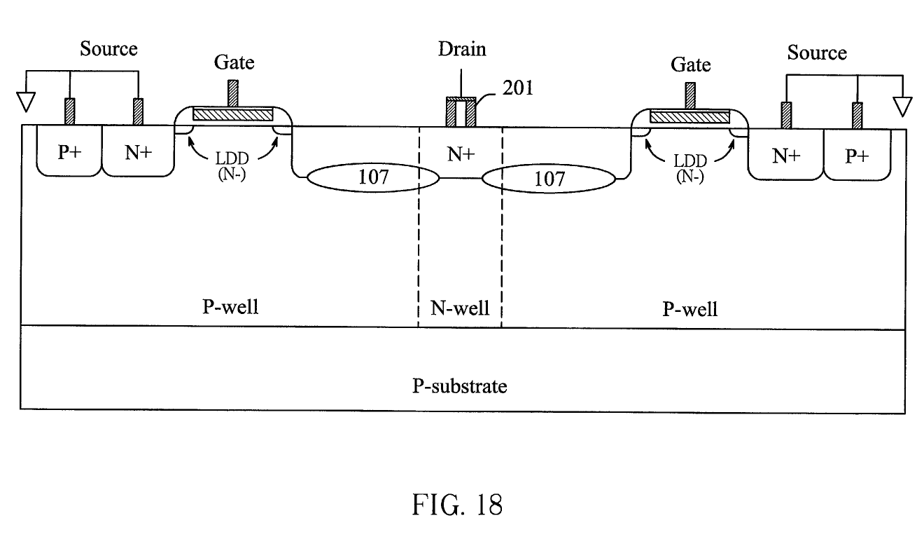

The similar implementation applies to the field-oxide device (FOD) for the robust ESD protection, for example, the N-type FOD illustrated in FIG. 17. The aforementioned ESD implantation region covers the drain junction of the FOD except the drain junction region right under the drain contact 301. The FOD device has a thicker shallow-trench-isolation (STI) oxide region between its drain and source regions. The FOD device can also be further formed with an additional N-well region as shown in FIG. 17 in order to overcome the contact-spiking effect. Alternatively, the additional N-well region can overlap the pattern of the ESD implantation region 107, as shown in FIG. 18.

While this invention has been described with reference to an illustrative embodiment, it is not intended that this description be construed in a limiting sense. Various modifications and combinations of the illustrative embodiment, as well as other embodiments of the invention, will be apparent to persons skilled in the art upon reference to the description. It is therefore intended that the appended claims encompass any such modifications or embodiments.

What is claimed is:

1. An ESD implantation method for manufacturing semiconductor devices having ESD (Electrostatic Discharge) protection, said method comprising the steps of:
providing a semiconductor substrate having a well region;
forming a gate structure on said semiconductor substrate, said gate structure including an oxide layer, a gate electrode on said oxide layer, and two spacer sidewalls;
forming a source region within said well region at one side of said gate structure;
forming a drain region within said well region at the other side of said gate structure;
forming lightly doped source/drain regions with the same conductivity type as said drain region, said lightly source/drain regions being formed in said well region and beneath said spacer walls of said gate structure; and
performing an implant with the same conductivity type as said well region as to form an ESD implantation region beneath said drain region by substantially surrounding a central area of said drain region wherein said central area vertically corresponds to the contact of said drain region.

2. The ESD implantation method as claimed in claim 1, wherein said ESD implantation region is formed as a plurality of small blocks disposed with an interval along either side of said drain region.

3. The ESD implantation method as claimed in claim 1, wherein the said ESD implantation region is formed in a comb shape.

4. An ESD implantation method for manufacturing semiconductor devices having ESD (Electrostatic Discharge) protection, said method comprising the steps of:
providing a semiconductor substrate having a first well region;
forming a gate structure on said semiconductor substrate, said gate structure including an oxide layer, a gate electrode on said oxide layer, and two spacer sidewalls;
forming a first well region within said first well region;
forming a source region within said first well region at one side of said gate structure;
forming a drain region within said first well region at the other side of said gate structure;
forming a second well region having the opposite impurity type to said first well region, said second well region being formed beneath the drain contact;
forming lightly doped source/drain regions with the same conductivity type as said drain region, said lightly doped source/drain regions being formed in said first well region and beneath said spacer walls of said gate structure; and
performing an implant with the same conductivity type as said first well region so as to form an ESD implantation region beneath said drain region by substantially surrounding said second well region vertically corresponding to the contact of said drain region.

5. The ESD implantation method as claimed in claim 4, wherein said second well region is separated from said ESD implantation region, or said second well region overlaps said ESD implantation region.

6. The ESD implantation method as claimed in claim 4, wherein said ESD implantation region is formed as a plurality of small blocks disposed with an interval along either side of said drain region.

7. The ESD implantation method as claimed in claim 4, wherein the said ESD implantation region is formed in a comb shape.
